(19) United States
(12) Patent Application Publication
(10) Pub. No.: US 2006/0263971 A1
(43) Pub. Date: Nov. 23, 2006

(54) Semiconductor device and method thereof

(75) Inventors: Kwang-Wook Lee, Seongnam-si (KR); Cheol-Woo Park, Suwon-si (KR); Yong-Sun Ko, Suwon-si (KR); Byoung-Moon Yoon, Suwon-si (KR); Kyung-Hyun Kim, Seoul (KR)

Correspondence Address: HARNESS, DICKEY & PIERCE, P.L.C., P.O. BOX 8910, RESTON, VA, 20195, US

(73) Assignee: Samsung Electronics Co., Ltd.

(21) Appl. No.: 11/436,582

(22) Filed: May 19, 2006

(30) Foreign Application Priority Data
May 20, 2005 (KR) 10-2005-0042385

(51) Int. Cl. B32B 3/10; B32B 3/00; H01L 21/8244; H01L 29/94

(52) U.S. Cl. 438/238; 428/131; 428/156; 257/296

(57) ABSTRACT

A semiconductor device and a method thereof are disclosed. In the example method, a mold layer having an opening may be formed on a substrate. A conductive etchable pattern (e.g., a preliminary conductive pattern, a lower electrode pattern, etc.) may be formed within the opening. The mold layer may be reduced so as to expose a portion of the conductive etchable pattern and less than all of the exposed portion of the conductive etchable pattern may be etched such that the etched conductive etchable pattern has a reduced thickness. The example semiconductor device may include the etched conductive etchable pattern as above-described with respect to the example method.

### PRIORITY STATEMENT

This application claims priority under 35 USC § 119 to Korean Patent Application No. 2005-42385 filed on May 20, 2005, the contents of which are herein incorporated by reference in their entirety.

### BACKGROUND OF THE INVENTION

1. Field of the Invention

Example embodiments of the present invention relate generally to a semiconductor device and method thereof, and more particularly to a semiconductor device and a method of manufacturing the semiconductor device.

2. Description of the Related Art

As wire widths of a dynamic random-access memory (DRAM) device decrease (e.g., below 100 nanometers (nm)), a cell area of the DRAM device may be reduced. A capacitor in a conventional DRAM device may be configured to improve a capacitance by modifying a structure thereof, for example, into a tube structure, a cylindrical structure or a mesh structure. However, if the DRAM device includes a smaller critical dimension (e.g., below about 0.1 μm), such that a cell area of a cell in the DRAM device may be very small, the above-described modified structure of the capacitor (e.g., tube, cylindrical, mesh, etc.) may have an aspect ratio of the capacitor which may increase so as to satisfy desired capacitance requirements for a semiconductor device, such as a DRAM device. If the aspect ratio of a cylindrical capacitor increases beyond a threshold, electrical shorts between adjacent capacitors may become more prevalent, which may be referred to as a 2-bit failure.

In order to reduce the occurrence of 2-bit failures, a lower electrode having a stepped portion may be employed. A polysilicon pattern having a cylindrical shape may be formed in a contact hole of a mold layer, and the mold layer may be etched to expose a portion of the polysilicon pattern. The exposed portion of the polysilicon pattern may be wet etched using a standard cleaning (SC-1) solution including NH4OH, H2O2 and H2O with a molecular ratio of about 1:4:20, respectively, to form a lower electrode having a stepped portion.

A storage node of the cylindrical shape including polysilicon may be formed in a contact hole of a mold layer, and an upper portion of the mold layer may be etched to partially expose the storage node. The exposed portion of the storage node may be dry etched using carbon fluoride and oxygen to form a lower electrode having a stepped portion.

In the above-described conventional methods of forming the capacitor, because the lower electrode of the capacitor may include polysilicon, a resistance between the capacitor and a pad may increase and a capacitance of the capacitor may thereby be reduced. A lower electrode including titanium nitride may be employed in place of the lower electrode including polysilicon in order to reduce the resistance and augment the capacitance of the capacitor.

However, if the lower electrode includes titanium nitride, the lower electrode may have a relatively high etching rate relative to the SC-1 solution. The SC-1 solution, which may be widely used for forming the lower electrode including polysilicon, may be difficult to utilize for forming the lower electrode having the stepped portion. Therefore, if the SC-1 solution is used in an etching process for forming the stepped portion at a lower electrode including titanium nitride, an etching rate of a conductive pattern, which may be partially etched to form the lower electrode, may be so rapid that a degree of etching of the conductive pattern may be difficult to control accurately. Accordingly, an exposed portion of the conductive pattern for forming the lower electrode may be over-etched or under-etched before the stepped portion may be formed at the lower electrode.

### SUMMARY OF THE INVENTION

An example embodiment of the present invention is directed to a method of manufacturing a semiconductor device, including forming a mold layer having an opening on a substrate, forming a conductive etchable pattern in the opening, reducing the mold layer to expose a portion of the conductive etchable pattern and etching less than all of the exposed portion of the conductive etchable pattern such that the etched conductive etchable pattern has a reduced thickness.

Another example embodiment of the present invention is directed to a semiconductor device, including a mold layer formed on a substrate, the mold layer including an opening and a conductive etchable pattern formed in the opening of the mold layer, the conductive etchable pattern including an etched portion with a lesser thickness and a non-etched portion with a greater thickness, the etched portion of the conductive etchable pattern corresponding to an exposed portion of the conductive etchable pattern exposed by a reduction of the mold layer.

Other example embodiments of the present invention are directed to methods of manufacturing a conductive pattern having a stable structure using an etching solution without over-etching a conductive pattern including a metal or a metal nitride.

Other example embodiments of the present invention are directed to methods of manufacturing a semiconductor device including a conductive pattern having a stable structure using an etching solution without over-etching a metal or a metal nitride.

### BRIEF DESCRIPTION OF THE DRAWINGS

The accompanying drawings are included to provide a further understanding of the invention, and are incorporated in and constitute a part of this specification. The drawings illustrate example embodiments of the present invention and, together with the description, serve to explain principles of the present invention.

FIGS. 1 to 5 are cross-sectional views illustrating a process of manufacturing a conductive pattern in accordance with an example embodiment of the present invention;

FIGS. 6 to 10 are cross-sectional views illustrating a process of manufacturing a conductive pattern in accordance with another example embodiment of the present invention; and

FIGS. 11 to 19 are cross-sectional views illustrating a process of manufacturing a semiconductor device in accordance with another example embodiment of the present invention.

### DETAILED DESCRIPTION OF EXAMPLE EMBODIMENTS OF THE PRESENT INVENTION

Example embodiments of the present invention are described more fully hereinafter with reference to the accompanying drawings, in which embodiments of the invention are shown. Example embodiments of the present invention may, however, be embodied in many different forms and should not be construed as limited to the embodiments set forth herein. Rather, these example embodiments are provided so that this disclosure will be thorough and complete, and will fully convey the scope of the present invention to those skilled in the art. In the drawings, the sizes and relative sizes of layers and regions may be exaggerated for clarity.

It will be understood that when an element or layer is referred to as being “on”, “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. Like numbers refer to like elements throughout. As used herein, the term “and/or” includes any and all combinations of one or more of the associated listed items.

It will be understood that, although the terms first, second, third etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the present invention.

Spatially relative terms, such as “beneath”, “below”, “lower”, “above”, “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular example embodiments only and is not intended to be limiting of the present invention. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Example embodiments of the present invention are described herein with reference to cross-section illustrations that are schematic illustrations of idealized embodiments (and intermediate structures) of the present invention. As such, variations from the shapes of the illustrations as a result, for example, of manufacturing techniques and/or tolerances, are to be expected. Thus, example embodiments of the present invention should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of the present invention.

Unless otherwise defined, all terms (including technical and scientific terms) used herein have the same meaning as commonly understood by one of ordinary skill in the art to which this present invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

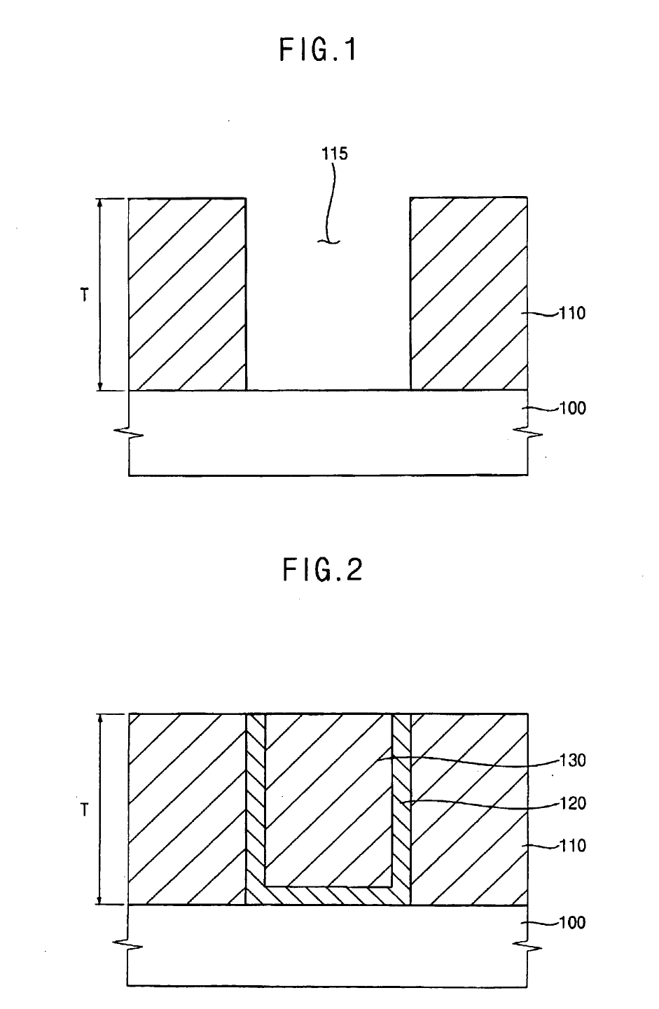

FIGS. 1 to 5 are cross-sectional views illustrating processing steps for a process of manufacturing a conductive pattern in accordance with an example embodiment of the present invention;

In the example embodiment of FIG. 1, a mold layer 10 having an opening 115 may be formed on a substrate 100. A preliminary mold layer (not shown) may be formed on the substrate 100 including a pad (not shown). The preliminary mold layer may be formed by depositing an insulating material. In an example, the preliminary mold layer may include an oxide layer such as a borophosphosilicate glass (BPSG) layer, a phosphosilicate glass (PSG) layer, an undoped silicate glass (USG) layer, a spin-on glass (SOG) layer, a tetraethylorthosilicate (TEOS) layer by a plasma-enhanced chemical vapor deposition (CVD) process (PE-TEOS layer) and an oxide layer deposited by a high-density plasma CVD process (HDP-CVD oxide layer). In a further example, the preliminary mold layer may have a thickness between about 5,000 to about 20,000 Å as measured from a top surface of the substrate 100. In an example, the thickness of the preliminary mold layer may vary in accordance with a desired height of a conductive pattern. Thus, the height of the conductive pattern may depend on the thickness of the preliminary mold layer.

In the example embodiment of FIG. 1, a mask pattern (not shown) having an etching selectivity with respect to the preliminary mold layer may be formed on the preliminary mold layer. In an example, if the preliminary mold layer includes an oxide, the mask pattern may include a nitride such as silicon nitride, silicon oxynitride, etc. The preliminary mold layer may be anisotropically etched off from the substrate 100, using the mask pattern as an etching mask, to form the mold layer 110 having the opening 115 through which a portion of the substrate 100 may be exposed. In an example, the mold layer 110 may have a thickness T between about 5,000 to about 20,000 Å as measured from a top surface of the substrate 100 (e.g., which may be substantially identical to that of the preliminary mold layer).

In the example embodiment of FIG. 1, in an alternative example, an etch-stop layer (not shown) may be further formed on the substrate 100, and the preliminary mold layer may be formed on the etch-stop layer, such that damage to the substrate 100 may be reduced during the etching process for forming the opening 151.

In the example embodiment of FIG. 2, a conductive pattern 120 may be formed on an inner wall of the opening 115, and a first buffer oxide pattern 130 may be formed on the conductive pattern 120 to at least partially fill the opening 115.

In the example embodiment of FIG. 2, a conductive layer (not shown) may be formed on the inner wall of the opening 115, the exposed portion of the substrate 100 and the mold layer 110. The conductive layer may be formed using a conductive material including a metal. In an example, the conductive layer may include one or more of tungsten (W), titanium (Ti), titanium nitride, tungsten nitride, etc. In another example, the conductive layer may have a structure including a single layer film and/or multiple layered films (e.g., a bilayer film).

In the example embodiment of FIG. 2, the conductive layer may be formed at a thickness sufficient to compensate for a reduction in a sidewall thickness of the conductive layer due to a subsequent etching process. For example, the conductive layer may be formed at a thickness between about 200 to about 500 Å.

In the example embodiment of FIG. 2, a buffer oxide layer (not shown) may be formed on the conductive layer at a thickness sufficient to at least partially fill (e.g., to completely fill) the opening 115. For example, the buffer oxide layer may include one or more of borophosphosilicate glass (BPSG), phosphosilicate glass (PSG), undoped silicate glass (USG), spin-on glass (SOG), plasma-enhanced tetraethylorthosilicate (PE-TEOS), high-density plasma chemical vapor deposition (HDP-CVD) oxide, atomic layer deposition (ALD) oxide, etc.

In the example embodiment of FIG. 2, the buffer oxide layer and the conductive layer may be partially removed by one or more reduction processes (e.g., a chemical mechanical polishing process, an etch back process or a combination thereof) until a top surface of the mold layer 110 may be exposed, such that the conductive layer and the buffer oxide layer may only remain substantially within the opening 115. Accordingly, a preliminary conductive pattern 120 may be formed on the inner wall of the opening 115 with a cylindrical shape, and a first buffer oxide pattern 130 may be formed on the preliminary conductive pattern 120 in the opening 115 concurrently with the preliminary conductive pattern 120. The first buffer oxide pattern 130 may protect the preliminary conductive pattern 120, for example, in a subsequent node separation process for forming a lower electrode of the capacitor, and in a subsequent etching process.

In the example embodiment of FIG. 2, if an aspect ratio of the opening 115, where the aspect ratio may refer to a ratio between a depth of the opening 115 to a diameter or width of the opening 115, is above an aspect ratio threshold, gap-filling characteristics of the buffer oxide layer may deteriorate and the first buffer oxide pattern 130 may have voids or seams therein. In another example, the first buffer oxide pattern 130 may have an etching rate greater than or equal to that of the mold layer 110.

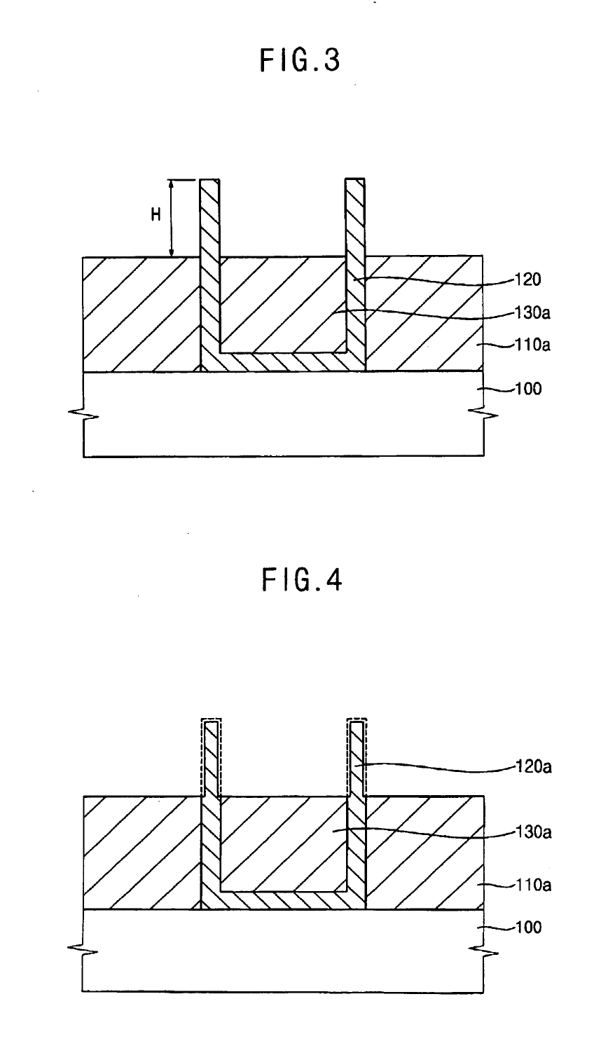

In the example embodiment of FIG. 3, the mold layer 110 may be partially etched from the substrate 100 to form a mold layer pattern 110a on the substrate 100, and a portion of the preliminary conductive pattern 120 may be exposed to a height H from an upper face of the mold layer pattern 110a.

In the example embodiment of FIG. 3, an etching process may be performed on the substrate 100 including the mold layer 110, the conductive pattern 120 and the first buffer oxide pattern 130. The mold layer 110 may thereby be partially etched off the substrate 100, such that the thickness of the mold layer 110 may be reduced so as to form the mold layer pattern 110a on the substrate 100. Further, the preliminary conductive pattern 120 may be exposed or may protrude to a height H from the upper face of the mold layer pattern 110.

In another example embodiment of the present invention, an etching rate of the preliminary conductive pattern 120 (e.g., including a conductive metal) may be relatively low and an etching rate of the mold layer 110 may be relatively high in an etching solution and/or in an etching gas for forming the mold layer pattern 110a.

In an example, referring to FIG. 3, the mold layer pattern 110a may be formed by a wet etching process using a Limulus Amoebocyte Lysate (LAL) solution including ammonium fluoride, hydrogen fluoride and de-ionized water. In another example, the mold layer pattern 110a may be formed by a dry etching process using a mixture of hydrogen fluoride (HF), isopropyl alcohol (IPA) and/or water vapor as an etching gas.

In another example, referring to FIGS. 2 and 3, the first buffer oxide pattern 130 may have an etching rate substantially identical to that of the mold layer 110. Therefore, the first buffer oxide pattern 130 may be etched off the substrate 100 to the same degree as the mold layer 110 and the etching of the first buffer oxide pattern 130 may be performed concurrently with the etching of the mold layer 110, thereby forming a second buffer oxide pattern 130a with a top surface that may be coplanar with a top surface of the mold layer pattern 110a. The preliminary conductive pattern 120 may thereby be exposed to the height H from the second buffer oxide pattern 130a.

In the example embodiment of FIG. 3, if the first buffer oxide pattern 130 includes a plurality of voids therein, the etching gas and/or the etching solution may penetrate into the voids in the first buffer oxide pattern 130 in the etching process for reducing the mold layer 110, such a given amount (e.g., most) of the first buffer oxide pattern 130 in the opening 115 may be removed from the substrate 100 concurrently with a reduction of the mold layer 110.

In the example embodiment of FIG. 3, a cleaning process may be performed on the substrate 100 including the mold layer pattern 110a and the second buffer oxide pattern 130a. The cleaning process may at least partially remove residual etching solution and particles remaining on the mold layer pattern 110a and the preliminary conductive pattern 120 from the substrate 100. In an example, the cleaning process may be performed by rinsing the substrate 100 using isopropyl alcohol (IPA) and/or deionized water.

In the example embodiment of FIG. 4, a portion of the preliminary conductive pattern 120 exposed from the mold layer pattern 110a may be further etched off from the substrate 100, such that a thickness of the exposed preliminary conductive pattern 120 may be reduced. Hereinafter, the preliminary conductive pattern 120 with a reduced thickness is referred to as a conductive pattern 120a. Accordingly, a stepped portion may be formed at the conductive pattern 120a due to the reduced thickness thereof in a subsequent process. In an example, the exposed portion of the preliminary conductive pattern 120 may be etched using an etching solution containing an aqueous ozone solution and/or a hydrofluoric acid solution.

In the example embodiment of FIG. 4, an etching rate of the mold layer pattern 110a may be lower than that of the preliminary conductive pattern 120 in the above etching solution. Accordingly, an etching amount or degree of the mold layer pattern 110a may be less than that of the preliminary conductive pattern 120. Thereby, the preliminary conductive pattern 120 may be etched off from the substrate 100 without substantially reducing the mold layer pattern 110a.

In the example embodiment of FIG. 4, the etching rate of the conductive pattern 120a may range between about 2 to about 10 Å/min. Further, the etching rate of the conductive pattern 120a may range between about 3 to about 7 Å/min. Furthermore, the etching rate of the conductive pattern 120a may range between about 4 to about 6 Å/min.

In the example embodiment of FIG. 4, if the conductive pattern 120a includes a polycrystalline structure with grain boundaries, an etching solution including the aqueous ozone solution and/or the hydrofluoric acid solution may not penetrate into an inner portion of the conductive pattern 120a along the grain boundaries. In an example, the hydrofluoric acid solution may have a volume ratio between about 1:500 to about 1:2,000 with respect to the aqueous ozone solution. For example, if the hydrofluoric acid solution has a volume of one liter, the aqueous ozone solution may have a volume of five hundred liters to two thousand liters. In another example, if the hydrofluoric acid solution has a volume ratio between about 1:500 to about 1:2,000 with respect to the aqueous ozone solution, the conductive pattern 120a may be etched off at an etching rate of about 2 to about 10 Å/min.

In the example embodiment of FIG. 4, if a volume ratio of the hydrofluoric acid solution with respect to the aqueous ozone solution is greater than about 1:500, the etching solution may have higher hydrofluoric acid solution content than that of the aqueous ozone solution. Thus, the mold layer pattern 110a and the preliminary conductive pattern 120 may have an increased etching rate because of the relatively high hydrofluoric acid solution content.

In the example embodiment of FIG. 4, if a volume ratio of the hydrofluoric acid solution with respect to the aqueous ozone solution is less than about 1:2,000, the etching solution may have lower hydrofluoric acid solution content than that of the aqueous ozone solution. Thus, the mold layer pattern 10a and the preliminary conductive pattern 120 may have a decreased etching rate because of the relatively low hydrofluoric acid solution content, such that the conductive pattern 120 oxidized by the aqueous ozone solution may not be cleaned sufficiently.

In another example embodiment of the present invention, the etching solution may include the hydrofluoric acid solution and the aqueous ozone solution with a volume ratio between about 1:500 to about 1:2,000. In another example, the etching solution may include the hydrofluoric acid solution and the aqueous ozone solution with a volume ratio between about 1:800 to about 1:1,800. In another example, the etching solution may include the hydrofluoric acid solution and the aqueous ozone solution with a volume ratio between about 1:1,000 to about 1:1,400. In another example, the aqueous hydrofluoric solution may include hydrofluoric acid at a concentration of about 40 to about 60 percent by weight. Further, the aqueous hydrofluoric solution may include hydrofluoric acid at a concentration of about 50 percent by weight.

In another example, referring to FIG. 4, the aqueous ozone solution may include ozone in deionized water at a concentration of about 10 to about 70 ppm. In other words, ozone having a liquid phase in the aqueous ozone solution may have a weight of about 10 to about 70 mg with respect to about 1 kg (e.g., 1,000 mL) of deionized water. In an example, ozone having a liquid phase may have a weight between about 20 to about 40 mg with respect to about 1 kg (e.g., 1,000 mL) of deionized water.

In the example embodiment of FIG. 4, in another example, the aqueous ozone solution may include deionized water with ozone having a concentration between about 10 to about 70 ppm. For example, ozone gas may be dissolved into deionized water at a concentration between about 10 to about 70 ppm to produce an aqueous ozone solution.

In another example, referring to FIG. 4, the above-described example mixture of the aqueous ozone solution and the aqueous hydrofluoric acid solution may be characterized in that a metal layer or a metal nitride layer may be etched off without excessive or over-etching in a wet etching process using the mixture as an etchant, such that the above-described example mixture of the aqueous ozone solution and the aqueous hydrofluoric acid solution may be utilized as an etchant for a wet etching process in which a stable pyramid structure and/or a stepped structure may be formed at a conductive pattern including metal and/or metal nitride.

In another example, referring to FIG. 4, the preliminary conductive pattern 120 may be etched by a thickness of about 30 to about 60 Å using the etching solution including the hydrofluoric acid solution and the aqueous ozone solution to form the conductive pattern 120a having the pyramid structure and/or the stepped portion.

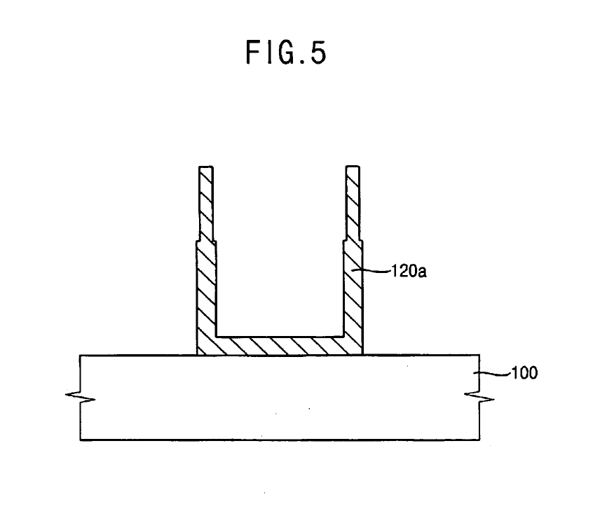

In the example embodiment of FIG. 5, the mold layer pattern 110a and the second buffer layer pattern 130a may be reduced (e.g., substantially removed) from the substrate 100 by a wet etching process using the same etchant as utilized for a wet etching process reducing an oxide layer, such that a lower portion of the conductive pattern 120a may be exposed and may remain on the substrate 100. As a result, the substrate 100 may be electrically connected to the conductive pattern 120a.

In the example embodiment of FIG. 5, the conductive pattern 120a may have a pyramid structure with a thickness which gradually decreases from a bottom portion to a top portion thereof. For example, a first etching step for partially removing the mold layer 110 and a second etching step for partially removing the preliminary conductive pattern 120 exposed by the first etching step may be repeated until the mold layer 110 may be substantially (e.g., completely) removed from the substrate 100, such that a plurality of the stepped portions may be formed at the sidewall of the conductive pattern 120a. As a result, as the first and second etching steps are repeated, the stepped portions may be formed more and more continuously or smoothly, such that the conductive pattern 120a may have the pyramid structure.

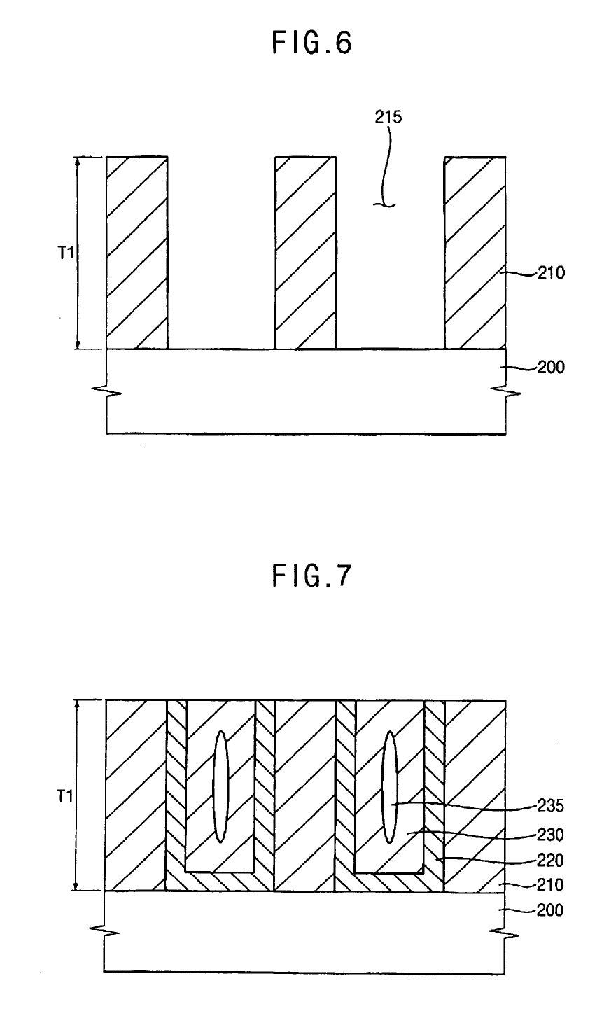

FIGS. 6 to 10 are cross-sectional views illustrating a process of manufacturing a conductive pattern in accordance with another example embodiment of the present invention.

In the example embodiment of FIG. 6, a preliminary mold layer (not shown) may be formed on the substrate 100 to a given thickness corresponding to a first thickness T1 in FIG. 6 of a mold layer 210 that may be formed by a subsequent etching process on the preliminary mold layer. In an example, the preliminary mold layer may include an oxide layer such as a BPSG layer, a PSG layer, a USG layer, an SOG layer, a PE-TEOS layer and an HDP-CVD oxide layer.

In the example embodiment of FIG. 6, a mask pattern (not shown) including nitride may be formed on the preliminary mold layer, and an anisotropic etching process may be performed on the preliminary mold layer using the mask pattern as an etching mask, to thereby form a mold layer 210 having an opening 215 through which a portion of the substrate 200 may be exposed.

In the example embodiment of FIG. 6, an etch-stop layer (not shown) may be further formed on the substrate 200, and the preliminary mold layer may be formed on the etch-stop layer, such that damage to the substrate 200 may be reduced or prevented during an etching process for forming the opening 215.

In the example embodiment of FIG. 7, a conductive layer (not shown) may be formed on the inner wall of the opening 215 and the mold layer 210. For example, the conductive layer may include one or more of tungsten, titanium, titanium nitride, tungsten nitride, etc.

In the example embodiment of FIG. 7, a buffer oxide layer (not shown) may be formed on the conductive layer to a sufficient thickness to at least partially fill the opening 215. In an example, the buffer oxide layer may have an etching rate greater than or equal to that of the mold layer 210.

In the example embodiment of FIG. 7, the buffer oxide layer and the conductive layer may be at least partially removed by a polishing process until a top surface of the mold layer 210 is exposed, such that the conductive layer and the buffer oxide layer may remain substantially within the opening 215. Accordingly, a preliminary conductive pattern 220 may be formed with a cylindrical shape along the inner wall of the opening 215, and a buffer oxide pattern 230 may be formed on the preliminary conductive pattern 220 in the opening 215 concurrently with the preliminary conductive pattern 220.

In the example embodiment of FIG. 7, if an aspect ratio of the opening 215 above an aspect ratio threshold, gap-filling characteristics of the buffer oxide layer may decrease and the buffer oxide pattern 230 may have voids 235 or seams therein. The buffer oxide pattern 230 may protect the preliminary conductive pattern 220 both in a subsequent node separation process for forming a lower electrode of the capacitor and in a subsequent etching process.

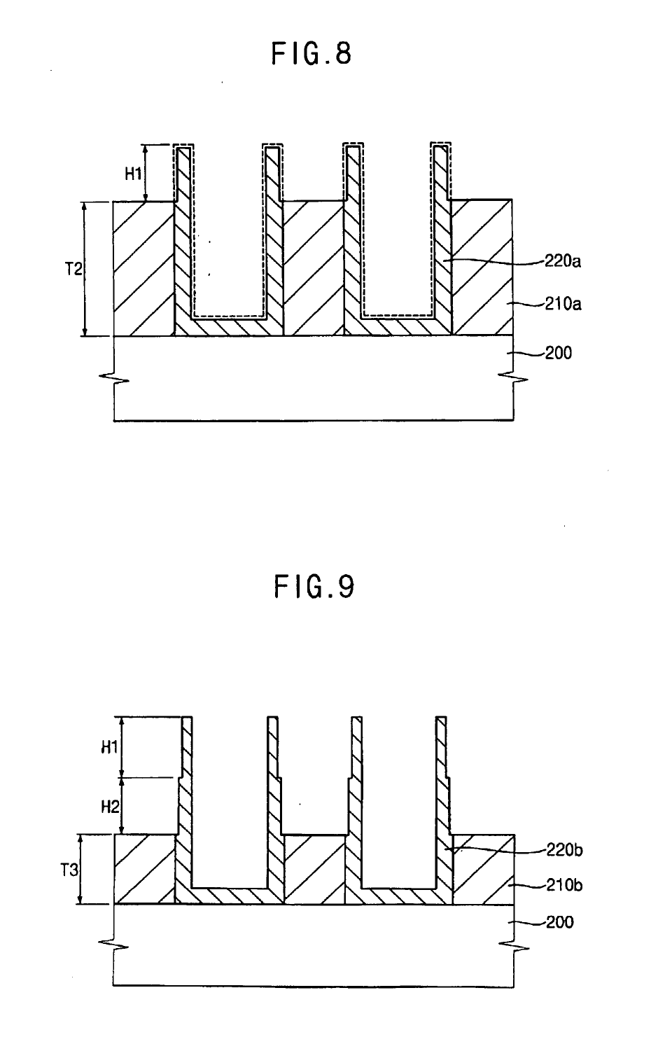

In the example embodiment of FIG. 8, the mold layer 210 may be partially etched off from the substrate 200, to thereby form a first mold layer pattern 210a having a second thickness 12. The preliminary conductive pattern 220 may be exposed and may protrude from the first mold layer pattern 210a to a first height H1 that may correspond to an etched portion or “thickness loss” of the mold layer 210.

In the example embodiment of FIG. 8, the buffer oxide pattern 230 may include a plurality of voids 235 therein. As a result, the etching gas or the etching solution may penetrate into the voids 235 in the buffer oxide pattern 230 during an etching process for reducing or removing the mold layer 210, such that a portion (e.g., a majority) of the buffer oxide pattern 230 in the opening 215 may be removed from the substrate 200 concurrently with the mold layer 210.

In the example embodiment of FIG. 8, an additional cleaning process may be further performed on the substrate 200 including the first mold layer pattern 210a, such that residual etching solution and particles remaining on the first mold layer pattern 210a and the preliminary conductive pattern 220 may be further removed from the substrate 200.

In the example embodiment of FIG. 8, a process of etching the mold layer 210 and the buffer oxide pattern 230 may be substantially identical to the process as described above with reference to FIG. 3. Accordingly, further description of the process of etching the mold layer 210 and the buffer oxide pattern 230 has been omitted for the sake of brevity.

In the example embodiment of FIG. 8, a portion of the preliminary conductive pattern 220 exposed and protruding from the first mold layer pattern 210a may be further etched from the substrate 200 using an etching solution including ozone and/or hydrofluoric acid, such that a thickness of the preliminary conductive pattern 220 may be partially reduced. Hereinafter, the preliminary conductive pattern 220 of which a thickness is partially reduced is referred to as a first conductive pattern 220a. A stepped portion may be formed at the conductive pattern due to the partially reduced thickness in a subsequent process.

In another example, referring to FIG. 8, the etching rate of the conductive pattern 220a may range between about 2 to about 10 Å/min. In another example, the etching rate of the conductive pattern 220a may range between about 3 to about 7 Å/min. In another example, the etching rate of the conductive pattern 220a may range between about 4 to about 6 Å/min.

In another example, referring to FIG. 8, the hydrofluoric acid solution and the aqueous ozone solution may be mixed so as to have a volume ratio of about 1:500 to about 1:2,000, such that the conductive pattern 220a may be etched off at an etching rate of about 2 to about 10 Å/min. Alternatively, the etching solution may include the hydrofluoric acid solution and the aqueous ozone solution with a volume ratio of about 1:800 to about 1:1,800. In another alternative example, the etching solution may include the hydrofluoric acid solution and the aqueous ozone solution with a volume ratio of about 1:1,000 to about 1:1,400.

In the example embodiment of FIG. 8, a process of forming the first conductive pattern 210a using the above etching solution may be substantially identical to the process as described with reference to FIG. 4. Accordingly, further description of the process of forming the first conductive pattern 210a using the above etching solution has been omitted for the sake of brevity.

In the example embodiment of FIG. 9, the first mold layer pattern 210a may be further partially etched off from the substrate 200 to thereby form a second mold layer pattern 210b having a third thickness T3, and to further expose a central portion of the preliminary conductive pattern 220 by a second height H2. In an example, the second height H2 may be smaller than the first height H1 of the exposed portion of the preliminary conductive pattern 220a. An additional cleaning process may be further performed to reduce or remove the etching solution and particles remaining on the substrate 200.

In the example embodiment of FIG. 9, a portion of the first conductive pattern 220a exposed by the second mold layer pattern 210b may be etched using an etching solution including an aqueous ozone solution and a hydrofluoric acid solution to form a second conductive pattern 220b having a decreased thickness of the exposed portion of the first conductive pattern 220a.

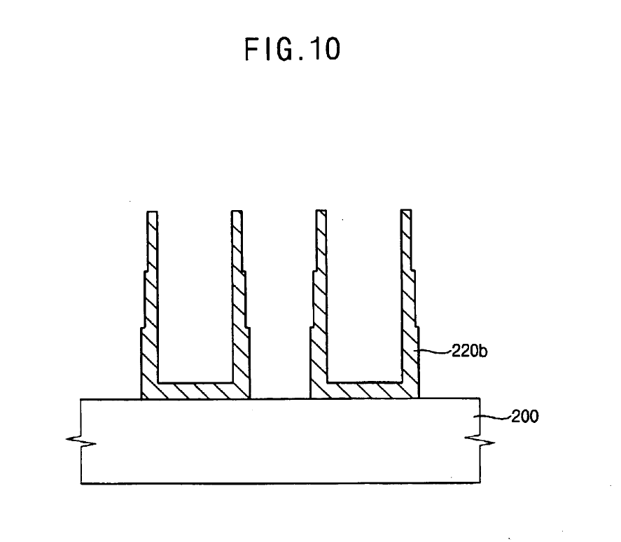

In the example embodiment of FIG. 10, the second mold layer pattern 210b may be reduced (e.g., completely removed) by a wet etching process to form the second conductive pattern 220b, which may be electrically connected to the substrate 200. The second conductive pattern 220b may be formed so as to have a pyramid structure.

In another example embodiment of the present invention, referring to FIG. 8, a first etching step for partially removing the mold layer 210 and a second etching step for partially removing the preliminary conductive pattern 220 exposed by the first etching step may be repeated until the mold layer 210 may be reduced (e.g., completely removed) from the substrate 200, such that a plurality of the stepped portions may be formed at the sidewall of the conductive pattern 220b. As the first and second etching steps are repeated, more stepped portions may be formed to generate a more continuous or smooth structure, such that the conductive pattern 220b may be said to have a pyramid structure.

In the example embodiment of FIG. 10, the process of manufacturing the conductive pattern having the above-described structure may be employed to form a variety of semiconductor devices, for example, a lower electrode of a capacitor. Hereinafter, a process of manufacturing a semiconductor device including a conductive pattern (e.g., formed in accordance with the above process described with respect to FIGS. 1-5 and/or 6-10) will be described in greater detail.

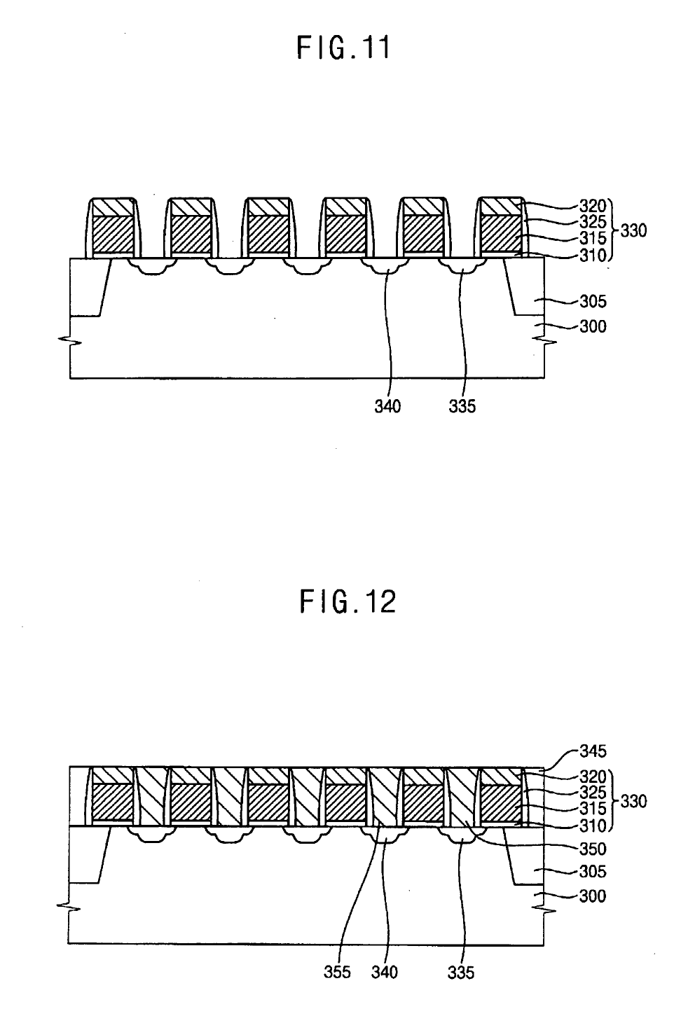

FIGS. 11 to 19 are cross-sectional views illustrating a process of manufacturing a semiconductor device in accordance with another example embodiment of the present invention. In particular, FIG. 11 illustrates a cross-sectional view illustrating a formation of a gate structure 330 and contact regions 335 and 340 on a semiconductor substrate 300 in accordance with another example embodiment of the present invention.

In the example embodiment of FIG. 11, an isolation layer 305 may be formed on the semiconductor substrate 300. The isolation layer 305 may be formed by an isolation process such as a shallow trench isolation (STI) process, a thermal oxidation process, a local oxidation of silicon (LOCOS), etc. An active region and a field region may be defined on the semiconductor substrate 300 if the isolation layer 305 is formed on the semiconductor substrate 300.

In the example embodiment of FIG. 1, a gate insulation layer (not shown) may be formed on the semiconductor substrate 300 including the isolating layer 305. The gate insulation layer may be formed on the active region, which may be defined by the isolation layer 305. The gate insulation layer may be formed by a thermal oxidation process, a chemical vapor deposition (CVD) process, etc.

In the example embodiment of FIG. 11, a first conductive layer (not shown) may be formed on the gate insulation layer. In an example, the first conductive layer may be formed using polysilicon doped with impurities and may be patterned to form a gate electrode 315. In another example, the conductive layer may have a polycide structure that includes a doped polysilicon film and a metal suicide film.

In the example embodiment of FIG. 11, a gate mask 320 may be formed on the first conductive layer. The gate mask 320 may be formed using a material having an etching selectivity relative to a first insulating interlayer (not shown) that may be subsequently formed on the semiconductor substrate 300. If the first insulating interlayer is formed using an oxide, the gate mask may be formed using a nitride such as silicon nitride, silicon oxynitride, etc.

In the example embodiment of FIG. 11, the first conductive layer and the gate insulation layer may be sequentially etched using the gate mask 320 as an etching mask, to thereby form the gate electrode 315 and the gate insulation layer pattern 310 on the semiconductor substrate 100. The gate structure 330 may include the gate insulation layer pattern 310, the gate electrode 315 and the gate mask 320.

In the example embodiment of FIG. 11, an insulation layer (not shown) may be formed on the semiconductor substrate 300 to at least partially cover the gate structure 330. The insulation layer may be formed using a nitride such as silicon nitride, silicon oxynitride, etc. The insulation layer may be anisotropically etched to form a gate spacer 325 on a sidewall of the gate structure 330. As a result, a plurality of word lines may be formed on the semiconductor substrate 300. Each of the word lines, which may be formed on the active region of the semiconductor substrate 300, may be electrically insulated from an adjacent word line by the gate spacer 325 (e.g., formed on the sidewall of the word line) and the gate mask 320.

In the example embodiment of FIG. 11, impurities may be implanted into surface portions of the semiconductors substrate 300 exposed between the gate structures 330 by an ion implantation process. The gate structure 330 including the gate spacer 325 may be employed as an ion implantation mask in an ion implantation process.

In the example embodiment of FIG. 11, after the ion implantation process is performed, a thermal treatment process may be performed to form a first contact region 335 and a second contact region 340 on a surface of the substrate 300. The first contact region 335 and the second contact region 340 may correspond to source/drain regions, respectively. The first and the second contact regions 335 and 340 may correspond to a capacitor contact region and a bit line contact region, respectively.

FIG. 12 is a cross-sectional view illustrating a formation of pads and a first insulating interlayer 345 in accordance with another example embodiment of the present invention.

In the example embodiment of FIG. 12, the first insulating interlayer 345 may be formed on the semiconductor substrate 300. The first insulating interlayer 345 may be formed using an oxide. In an example, the first insulation interlayer 345 may include one or more of BPSG, PSG, USG, SOG, PE-TEOS, HDP-CVD oxide, etc.

In the example embodiment of FIG. 12, the first insulating interlayer 345 may be planarized until an upper face of the gate structure 330 is exposed with a chemical mechanical polishing (CMP) process, an etch-back process or a combination process of CMP and etch-back.

In the example embodiment of FIG. 12, after a first photoresist pattern (not shown) is formed on the first insulating interlayer 345, an exposed portion of the first insulating interlayer 345 may be etched with an etching process using the first photoresist pattern as an etching mask, to thereby form first contact holes (not shown) in the first insulating interlayer 345. The first contact holes may expose the first and the second contact regions 335 and 340.

In the example embodiment of FIG. 12, if the first insulating interlayer 345 including the oxide is partially etched, the gate mask 320 may have an etching selectivity relative to the first insulating interlayer 345. Thus, the first contact holes may be formed in a self-aligned process relative to the gate structure 330. One or more of the first contact holes may expose the first contact region 335 corresponding to the capacitor contact region. One or more other of the first contact holes may expose the second contact region 340 corresponding to the bit line contact region.

In the example embodiment of FIG. 12, after the first photoresist pattern is reduced or removed (e.g., by an ashing process and/or a stripping process), a second conductive layer (not shown) may be formed on the first insulating interlayer 345 to at least partially fill the first contact holes. The second conductive layer may be formed using a conductive material such as doped polysilicon, a conductive metal nitride, and/or a metal. For example, the second conductive layer may include one or more of titanium nitride, aluminum nitride, titanium aluminum nitride, tungsten, aluminum, titanium, copper, etc.

In the example embodiment of FIG. 12, the second conductive layer may be planarized until an upper face of the first insulating interlayer 345 is exposed. For example, the second conductive layer may be planarized by a CMP process, an etch-back process or a combination process of CMP and etch-back. Thus, a first contact pad 350 and a second contact pad 355 at least partially filling the first contact holes may be formed on the first contact region 335 and the second contact region 340, respectively. The first pad 350 may be formed on the first contact region 335 corresponding to the capacitor contact region, and the second contact region 355 may be formed on the second contact region 340 corresponding to the bit line contact region.

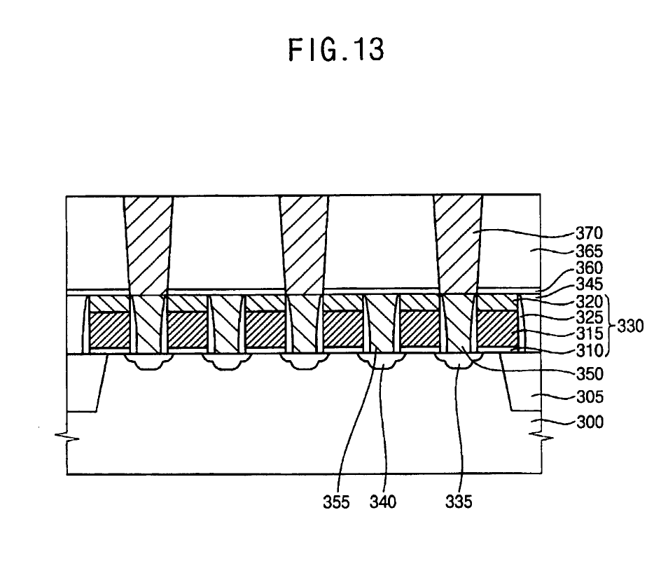

FIG. 13 is a cross-sectional view illustrating a process of forming a second insulating interlayer 360, a third insulating interlayer 365, a third pad and a fourth pad 370 according to another example embodiment of the present invention.

In the example embodiment of FIG. 13, the second insulating interlayer 360 may be formed on the first and the second contact pads 350 and 355 and the first insulating interlayer 345. The second insulating interlayer 360 may electrically insulate a bit line from the first pad 350. The second insulating interlayer 360 may be formed using an insulating material including one or more of BPSG, PSG, USG, SOG, HDP-CVD oxide, etc.

In the example embodiment of FIG. 13, a second photoresist pattern (not shown) may be formed on the second insulating interlayer 360. The second insulating interlayer 360 may be partially etched using the second photoresist pattern as an etching mask to form a second contact hole (not shown) in the second insulating interlayer 360. The second contact hole may expose the second pad 355. A third pad (not shown), which electrically connects the bit line to the second contact pad 355, may be formed on the second contact pad 355 to at least partially fill the second contact hole.

In the example embodiment of FIG. 13, after the second photoresist pattern is removed, a third conductive layer (not shown) and a bit line mask (not shown) may be sequentially formed on the second insulating interlayer 360. A portion of the third conductive layer exposed by the bit line mask may be patterned to form the third pad (not shown) on the second contact region 340 to at least partially fill the second contact hole. If the third pad is formed on the second contact region 340, the bit line including a bit line electrode (not shown) and the bit line mask may be concurrently formed on the second insulating interlayer 360. The third pad may electrically connect the bit line with the second pad 355.

In the example embodiment of FIG. 13, after a nitride layer (not shown) is formed on the second insulating interlayer 360 and the bit line, the nitride layer may be anisotropically etched to form a bit line spacer (not shown) on a sidewall of the bit line. The bit line spacer may protect the bit line from damage in a subsequent process for forming a fourth pad 370.

In the example embodiment of FIG. 13, a third insulating interlayer 365 may be formed on the second insulating interlayer 360 to cover the bit line including the bit line spacer. The third insulating interlayer 365 may be formed using an oxide, such as one or more of BPSG, PSG, USG, PE-TEOS, SOG, HDP-CVD oxide, etc. The third insulating interlayer 365 may be further planarized by a CMP process to have a planarized upper face thereof.

In the example embodiment of FIG. 13, after a third photoresist pattern (not shown) is formed on the third insulating interlayer 365, a portion of the third insulating interlayer 365 exposed by the third photoresist pattern and a portion of the second insulating interlayer 360 may be sequentially etched to form a third contact hole (not shown). The third contact hole may be formed with a self-aligned process relative to the bit line spacer.

In the example embodiment of FIG. 13, a fourth conductive layer (not shown) may be formed on the third insulating interlayer 365 to at least partially fill the third contact hole. The fourth conductive layer may be planarized until upper faces of the third insulating interlayer 365 and the bit line may be exposed by a CMP process to form a fourth pad 370, thereby at least partially filling the third contact hole.

In the example embodiment of FIG. 13, the fourth pad 370, which may be electrically connected to the first pad 350, may be formed using a conductive material including one or more of doped polysilicon, a conductive metal nitride and/or a metal. In an example, the fourth pad 370 may include one or more of titanium nitride, aluminum nitride, titanium aluminum nitride, tungsten, aluminum, titanium, copper, etc. The fourth pad 370 may electrically connect the first pad 350 with a lower electrode (e.g., which may be formed in a subsequent process).

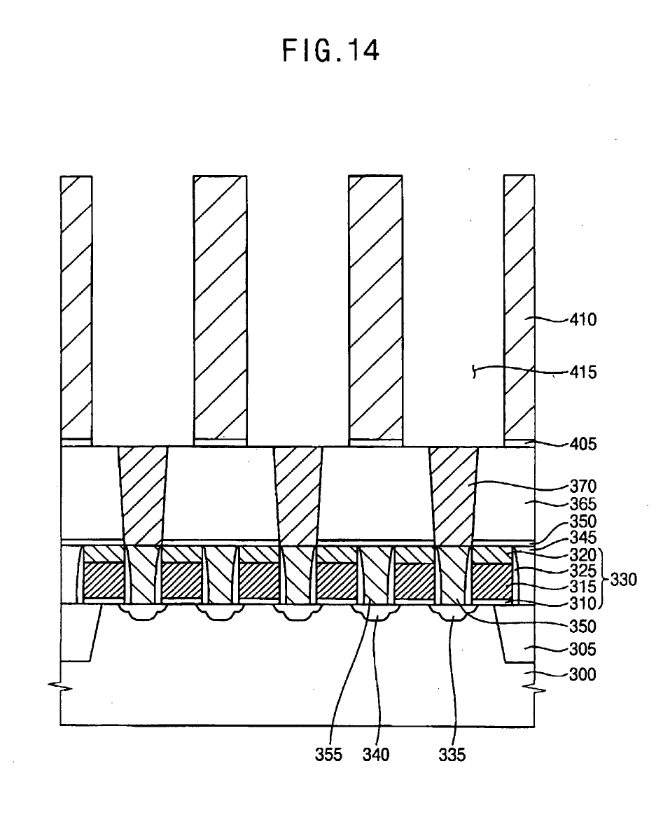

FIG. 14 is a cross-sectional view illustrating a formation of an etch-stop layer 405 and a mold layer 410 having an opening 415 according to another example embodiment of the present invention.

In the example embodiment of FIG. 14, the etch-stop layer 405 may be formed on the fourth pad 370, the third insulating interlayer 365 and the bit line. The etch-stop layer 405 may be formed on the fourth pad 370 so as to reduce damage to the fourth pad 370 during a formation of the opening 415 in the mold layer 410.

In the example embodiment of FIG. 14, the etch-stop layer 415 may have a thickness between about 10 to about 300 Å. The etch-stop layer 415 may include a material that has an etching selectivity relative to a mold layer 410. For example, the etch-stop layer may include nitride and/or metal nitride having a relatively low etching rate. In an example, the mold layer 410 may be formed on the etch-stop layer 415. The mold layer 210 may have a thickness between about 10,000 to about 20,000 Å as measured from an upper face of the etch-stop layer 415. The thickness of the mold layer 410 may vary in accordance with a desired capacitance of the capacitor. For example, a height of the capacitor, which may be a factor in determining a capacitance of the capacitor, may be determined based on the thickness of the mold layer 410. Thus, the thickness of the mold layer 410 may be controlled to obtain a desired capacitance of the capacitor.

In the example embodiment of FIG. 14, after a mask pattern (not shown) having an etching selectivity relative to the mold layer 410 is formed on the mold layer 410, the mold layer 410 may be partially etched using the mask pattern as an etching mask to form an opening 415 through which the etch-stop layer 405 may be partially exposed. Further, a portion of the etch-stop layer 405 exposed through the opening 415 may be reduced (e.g., removed) so as to expose the fourth contact pad 370.

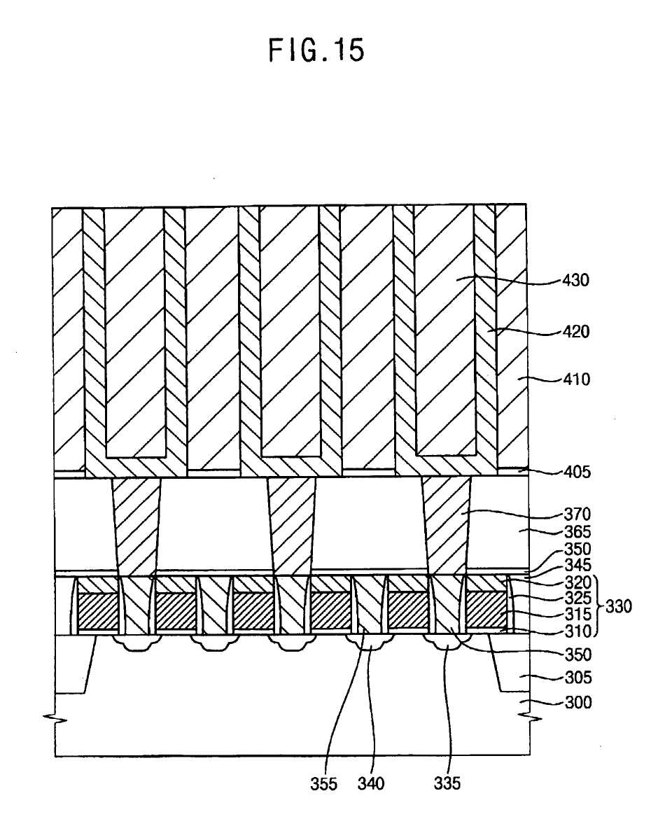

FIG. 15 is a cross-sectional view illustrating a formation of the preliminary lower electrode pattern 420 and a planarized buffer layer 430 according to another example embodiment of the present invention.

In the example embodiment of FIG. 15, a lower electrode layer (not shown) may be continuously formed on an inner wall of the opening 415 and the mask pattern. The lower electrode layer may include one or more of doped polysilicon, metal, a conductive metal nitride such as titanium nitride, etc. The lower electrode layer may be formed to a sufficient thickness to compensate for an etched portion or “thickness loss” of a sidewall of the lower electrode layer due to a subsequent etching process. In an example, the lower electrode layer may have a thickness between about 300 to about 1,000 Å.

In the example embodiment of FIG. 15, the buffer layer (not shown) may be formed on the lower electrode layer, thereby at least partially filling the opening 415. In an example, the buffer layer may an oxide, such as one or more of BPSG, PSG, USG, SOG, PE-TEOS, and/or HDP-CVD oxide.

In the example embodiment of FIG. 15, the lower electrode layer and the buffer layer may be planarized until an upper face of the mold layer 410 may be exposed to concurrently form the preliminary lower electrode pattern 420 and the planarized buffer layer 430 on an inner wall of the opening 415. The lower electrode layer and the buffer layer may be planarized by a CMP process, an etch-back process, or a combination process of CMP and etch-back.

In the example embodiment of FIG. 15, the planarized buffer layer 430 may protect the low electrode layer both in a subsequent node separation process forming the preliminary lower electrode pattern 420 and in a subsequent etching process for reducing (e.g., removing) the mold layer 410.

In the example embodiment of FIG. 15, if the opening 415 on which the preliminary lower electrode pattern 420 is formed is relatively high, the planarized buffer layer 430 may have poor gap-filling characteristics. Thus, the planarized buffer layer 430 formed in the opening 415 may have voids (not shown). In an example, the planarized buffer layer 430 may have an etching rate substantially identical to the mold layer 410.

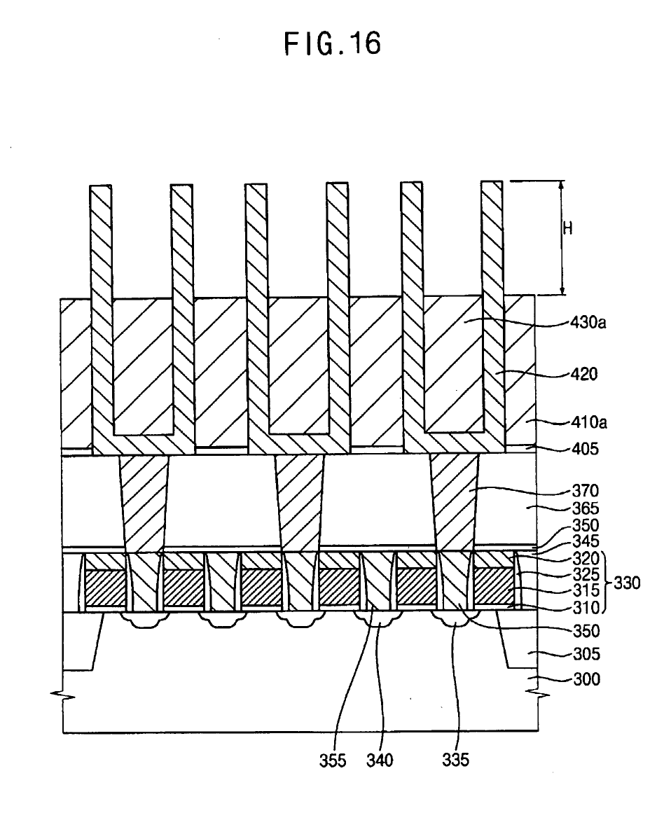

FIG. 16 is a cross-sectional view illustrating a formation of a mold layer pattern 410a partially exposing the preliminary lower electrode pattern 420 and a buffer layer pattern 430a according to another example embodiment of the present invention.

In the example embodiment of FIG. 16, the mold layer 410 and the buffer layer 430 may be partially etched away from the substrate 300 by a height H to form a mold layer pattern 410a and a buffer layer pattern 430a. Thus, sidewalls of the preliminary lower electrode pattern 420 may be exposed by a height H from an upper face of the mold layer pattern 410a.

In the example embodiment of FIG. 16, if an etching solution or an etching gas is used for etching the mold layer 410, the preliminary lower electrode pattern 420 (e.g., containing metal) may have a relatively low etching rate, whereas the mold layer 110 may have a relatively high etching rate. In an example, the mold layer pattern 410a and the buffer layer pattern 430a may be formed by a wet etching process using an LAL solution including ammonium fluoride, hydrogen fluoride and distilled water. In another example, the mold layer pattern 410a and the buffer layer pattern 430a may be formed by a dry etching process using a mixture of hydrogen fluoride, isopropyl alcohol (IPA), and/or water vapor.

In another example embodiment of the present invention, referring to FIG. 16, the buffer layer 430 may include a plurality of voids therein, such that the etching gas or the etching solution may penetrate into the voids in the buffer layer 430 in the etching process for reducing (e.g., removing) the mold layer 410, and a portion (e.g., a majority) of the buffer layer 430 in the opening 415 may be removed from the substrate 400 concurrently with the mold layer 410. A cleaning process may be performed on the substrate 400 including the mold layer pattern 410a and the buffer layer pattern 430a, such that residual etching solution and particles remaining on the mold layer pattern 410a and the preliminary lower electrode pattern 420 may be reduced (e.g., removed) from the substrate 400. In an example, the cleaning process may be performed by rinsing the substrate 200 with IPA and/or deionized water.

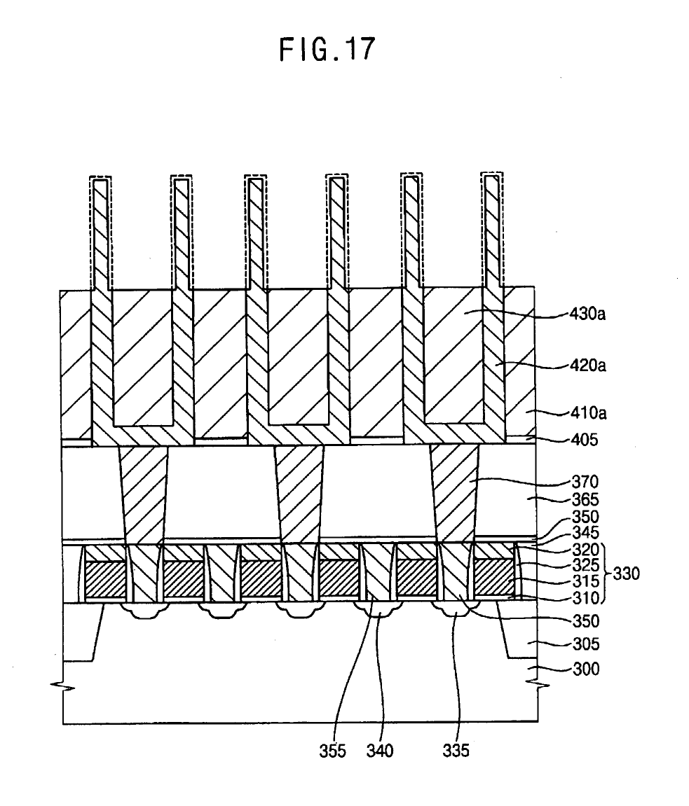

FIG. 17 is a cross-sectional view illustrating a formation of a lower electrode pattern 420a according to another example embodiment of the present invention.

In the example embodiment of FIG. 17, a portion of the preliminary lower electrode pattern 420 exposed from the mold layer pattern 410a and the buffer layer pattern 430a may be further etched, such that a thickness of the exposed preliminary lower electrode pattern 420 may be partially reduced. Hereinafter, the preliminary lower electrode pattern 420 having a partially reduced thickness may be referred to as a lower electrode pattern 420a. A stepped portion may be formed at the lower electrode pattern 420a due to the partially reduced thickness thereof in a subsequent process.

In the example embodiment of FIG. 17, if an etching solution is used for etching the preliminary lower electrode pattern 420, the preliminary lower electrode pattern 420 may have an etching rate between about 2 to about 10 Å/min. In an alternative example, the preliminary lower electrode pattern 420 may have an etching rate between about 3 to about 7 Å/min. In another alternative example, the preliminary lower electrode pattern 420 may have an etching rate between about 4 to about 6 Å/min.

In another example embodiment of the present invention, referring to FIG. 17, the hydrofluoric acid solution may have a volume ratio between about 1:500 to about 1:2,000 with respect to the aqueous ozone solution. In an example, if the hydrofluoric acid solution has a volume of one liter, the aqueous ozone solution may have a volume of five hundred liters to two thousand liters. If the hydrofluoric acid solution has a volume ratio between about 1:500 to about 1:2,000 with respect to the aqueous ozone solution, the preliminary lower electrode pattern 420a may be etched off at an etching rate between about 2 to about 10 Å/min.

In the example embodiment of FIG. 17, in an example, the etching solution may include the hydrofluoric acid solution and the aqueous ozone solution with a volume ratio of about 1:800 to about 1:1,800. In an alternative example, the etching solution may include the hydrofluoric acid solution and the aqueous ozone solution with a volume ratio of about 1:1,000 to about 1:1,400.

In the example embodiment of FIG. 17, in an example, the hydrofluoric acid solution may include hydrofluoric acid at a concentration of about 40 to about 60 percent by weight. In a further example, the hydrofluoric acid solution may include hydrofluoric acid at a concentration of about 50 percent by weight.

In the example embodiment of FIG. 17, in an example, the aqueous ozone solution may include ozone at a concentration of about 10 to about 70 ppm. In a further example, the aqueous ozone solution may include ozone having a liquid phase at a concentration of about 20 to about 70 ppm. In other words, ozone may have a weight of about 20 to about 40 mg with respect to about 1 kg (e.g., 1,000 mL) of deionized water.

In the example embodiment of FIG. 17, the etching solution at the above-example composition may be used as the etchant. The preliminary lower electrode pattern 420 including metal and/or metal nitride may be etched with the etchant to form the lower electrode pattern 420a having a given structure (e.g., pyramid structure, a stepped portion, etc.).

In the example embodiment of FIG. 17, in another example, the preliminary lower electrode pattern 420 may be etched by a thickness between about 30 to about 60 Å using the etching solution including the hydrofluoric acid solution and the aqueous ozone solution to form the lower electrode pattern 420a having the given structure (e.g., pyramid structure, a stepped portion, etc.).

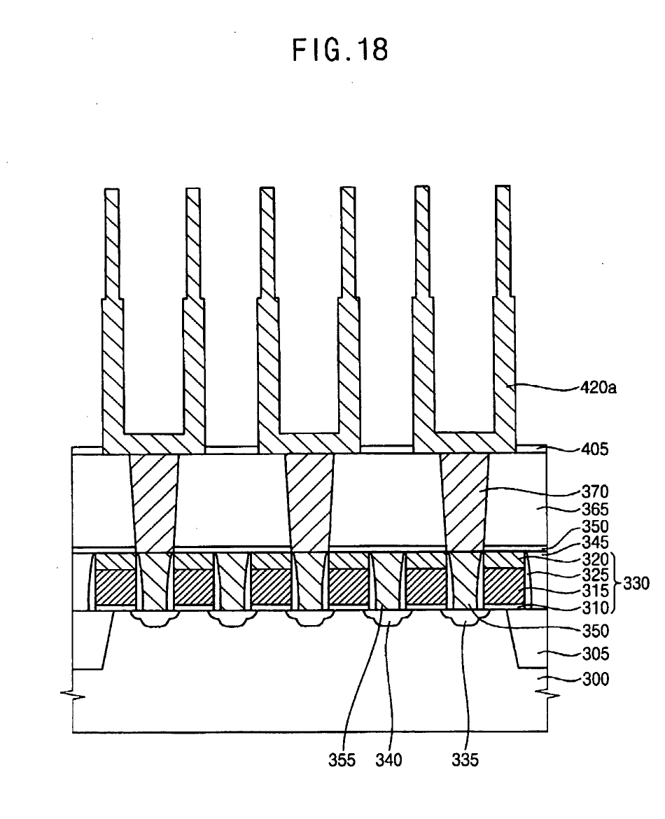

FIG. 18 is a cross-sectional view illustrating a reduction of the mold layer pattern 410a and the buffer layer pattern 430a according to another example embodiment of the present invention.

In the example embodiment of FIG. 18, the mold layer pattern 410a and the buffer layer pattern 430a may be at least partially (e.g., completely) removed to form a lower electrode 420a that may be electrically connected to the fourth pad 370.

In the example embodiment of FIG. 18, a process of partially etching the mold layer 410 and decreasing a thickness of the exposed portion of the preliminary lower electrode pattern 420 using the etching solution may be performed repeatedly to form the lower electrode 420 having the pyramid structure.

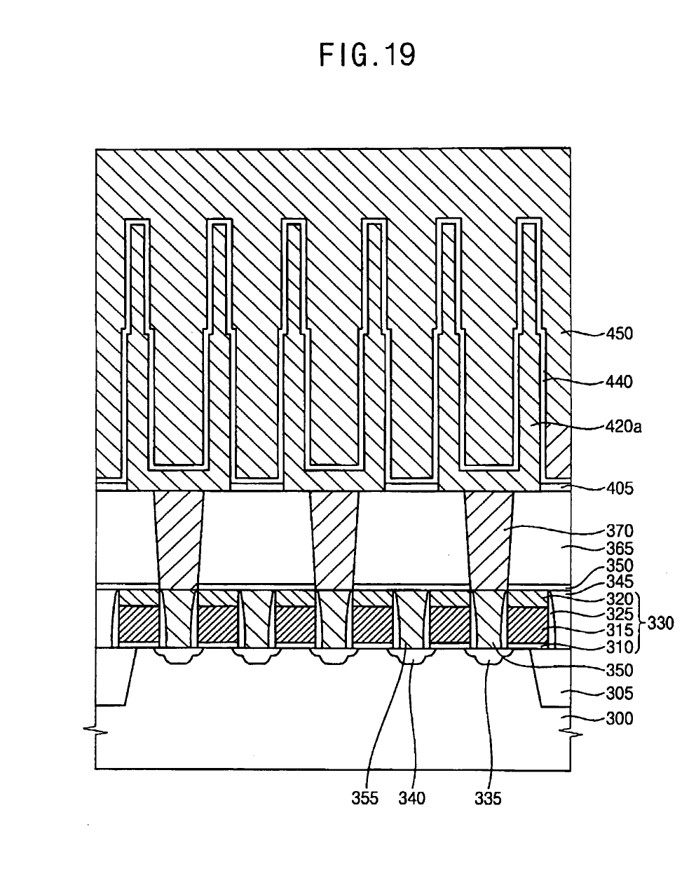

FIG. 19 is cross-sectional view illustrating a process of forming a dielectric layer 440 and an upper electrode 450 according to another example embodiment of the present invention.

In the example embodiment of FIG. 19, the dielectric layer 440 may be formed on the lower electrode 420a. In an example, the dielectric layer 440 may be formed by an atomic layer deposition (ALD) process, a CVD process, etc. If the dielectric layer 440 is formed by the ALD process, the dielectric layer 440 may include one or more of an aluminum oxide layer having aluminum oxide and/or a hafnium oxide layer.

In the example embodiment of FIG. 19, the upper electrode 450 may be formed on the dielectric layer 440. The upper electrode 450 may include a conductive material including one or more of polysilicon, metal, metal nitride, etc. In a further example, the upper electrode 450 may be formed by a CVD process. Accordingly, a capacitor including the lower electrode 420a, the dielectric layer 440 and the upper electrode 450 may be formed on the substrate 300.

In the example embodiment of FIG. 19, a lower electrode layer having metal and/or metal nitride may be etched at an etching rate between about 3 to about 7 Å/min using an etching solution including a hydrofluoric acid solution and/or an aqueous ozone solution. Thus, a lower electrode may have a thickness which decreases away from a substrate.

In the example embodiment of FIG. 19, if the lower electrode including metal nitride is formed having a stepped portion at a sidewall thereof using an etching solution, an etching rate of the lower electrode may be controlled so as to prevent a preliminary lower electrode from being over-etched. Accordingly, a capacitor including the above lower electrode may not lean, such that an occurrence of 2-bit error between adjacent capacitors may be reduced.

Example embodiments of the present invention being thus described, it will be obvious that the same may be varied in many ways. For example, while specific ranges of concentrations, thicknesses, etc. are described above, it is understood that any specific ranges are given for example purposes only, and other example embodiments of the present invention may include characteristics falling outside of the above-example ranges. Further, the term “between” is intended to be inclusive of the bounds of the example range. For example, a range between 1 to 3 is intended to include both 1 and 3.

Such variations are not to be regarded as a departure from the spirit and scope of example embodiments of the present invention, and all such modifications as would be obvious to one skilled in the art are intended to be included within the scope of the following claims.

What is claimed is:

1. A method of manufacturing a semiconductor device, comprising:
forming a mold layer having an opening on a substrate;
forming a conductive etchable pattern in the opening;
reducing the mold layer to expose a portion of the conductive etchable pattern; and
etching less than all of the exposed portion of the conductive etchable pattern such that the etched conductive etchable pattern has a reduced thickness.

2. The method of claim 1, wherein the conductive etchable pattern is a preliminary conductive pattern.

3. The method of claim 2, wherein the preliminary conductive pattern is formed on a sidewall and a bottom face of the opening.

4. The method of claim 1, wherein the etching uses an etching solution including ozone and hydrofluoric acid.

5. The method of claim 4, wherein the etching solution is prepared by mixing a hydrofluoric acid solution and an aqueous ozone solution with a respective volume ratio between about 1:500 to about 1:2,000.

6. The method of claim 5, wherein the hydrofluoric acid solution includes hydrofluoric acid at a concentration between about 40 to about 60 percent by weight.

7. The method of claim 5, wherein the aqueous ozone solution includes ozone having a liquid phase at a concentration between about 10 to about 70 ppm.

8. The method of claim 2, wherein the preliminary conductive pattern has an etching rate between about 3 to about 7 Å/min.

9. The method of claim 1, further comprising:
forming a buffer layer to at least partially fill the opening.

10. The method of claim 2, wherein forming the preliminary conductive pattern includes:
forming a conductive layer on the mold layer, a sidewall of the opening, and a bottom face of the opening;
forming a buffer layer on the mold layer to at least partially fill the opening; and
forming the preliminary conductive pattern by planarizing the buffer layer and the conductive layer until an upper face of the mold layer is exposed.

11. The method of claim 10, wherein at least one of the mold layer and the buffer layer includes an oxide.

12. The method of claim 10, wherein planarizing the buffer layer and the conductive layer includes a chemical mechanical polishing (CMP) process.

13. The method of claim 2, wherein the preliminary conductive pattern includes at least one of tungsten, titanium, tungsten nitride and titanium nitride.

14. The method of claim 1, further comprising:
repeating the reducing and etching steps until the mold layer is completely removed.

15. The method of claim 1, further comprising:
reducing a residual mold layer.

16. The method of claim 1, wherein the conductive etchable pattern is a lower electrode pattern and the etched conductive etchable pattern is a lower electrode having a reduced thickness as compared to the conductive etchable pattern.

17. The method of claim 16, further comprising:
forming the lower electrode pattern on a sidewall of the opening and an upper face of the opening;
forming a buffer layer pattern on the lower electrode pattern to at least partially fill the opening;
forming a dielectric layer on the lower electrode; and
forming an upper electrode on the dielectric layer.

18. The method of claim 17, wherein the lower electrode pattern and the buffer layer pattern are formed concurrently.

19. The method of claim 17, wherein forming the lower electrode pattern includes:
forming a lower electrode layer on the mold layer, the sidewall of the opening and the upper face of the opening;
forming a buffer layer on the lower electrode layer to at least partially fill the opening; and
forming the lower electrode pattern by planarizing the buffer layer and the lower electrode layer until an upper face of the mold layer is exposed.

20. The method of claim 17, wherein the buffer layer pattern includes at least one void.

21. The method of claim 17, wherein reducing the mold layer includes reducing the buffer layer pattern.

22. The method of claim 17, wherein the lower electrode pattern includes at least one of tungsten, titanium, tungsten nitride and titanium nitride.

23. A semiconductor device, comprising:
a mold layer formed on a substrate, the mold layer including an opening; and
a conductive etchable pattern formed in the opening of the mold layer, the conductive etchable pattern including an etched portion with a lesser thickness and a non-etched portion with a greater thickness, the etched portion of the conductive etchable pattern corresponding to an exposed portion of the conductive etchable pattern exposed by a reduction of the mold layer.

24. The semiconductor device of claim 23, wherein the conductive etchable pattern is one of a preliminary conductive pattern and a lower electrode pattern.

25. A method of manufacturing the semiconductor device of claim 23.
